(19) United States
(12) Patent Application Publication
(10) Pub. No.: US 2002/0132496 A1
(43) Pub. Date: Sep. 19, 2002

(54) Ultra low-k dielectric materials

(76) Inventors: Ian J. Ball, San Diego, CA (US); Qin Jang, Calabasas, CA (US); Yuwen Shi, Sylmar, CA (US)

Correspondence Address: SHELDON & MAK, 9th Floor, 225 South Lake Avenue, Pasadena, CA, 91101, US

(21) Appl. No.: 10/071,134

(22) Filed: Feb. 8, 2002

Related U.S. Application Data
(60) Provisional application No. 60/267,921, filed on Feb. 12, 2001.

(51) Int. Cl. H01L 21/31

(52) U.S. Cl. 438/780

(57) ABSTRACT

The invention relates to a dielectric composition and a process for forming an integrated circuit using the composition. The dielectric composition comprises a polymer precursor that upon heating to a cure temperature cross-links to form an organic polysilica layer and a sufficient amount of porogen that the layer has a porosity of from about 5% to about 80%. The porogen is non-reactive with the polymer precursor. Upon heating to a decomposition temperature, the porogen decomposes to form a gas that diffuses out of the layer.

### CROSS REFERENCE TO RELATED APPLICATIONS

This application claims the benefit of U.S. Provisional Application No. 60/267,921 filed on Feb. 12, 2001, which is incorporated herein by reference.

### STATEMENT REGARDING FEDERALLY SPONSORED RESEARCH OR DEVELOPMENT

This invention was made with Government support under Contract F33615-98-C-1336 awarded by the Department of the Air Force. The Government has certain rights in the invention.

### BACKGROUND

The present invention relates generally to films having a low dielectric constant for use in the fabrication of electronic and semiconductor devices such as integrated circuits.

As the semiconductor industry introduces new generations of integrated circuits (IC's) having higher performance and greater functionality, the density of the elements that form those IC's is increased, while the dimensions, size and spacing between the individual components or elements are reduced. While in the past such reductions were limited only by the ability to define the structures photolithographically, device geometries having dimensions as small as 0.25 micron (μm) or smaller have created a new limiting factors, such as the conductivity of the metallic elements or the dielectric constant of the insulating material(s) used between the elements.

For example, for any two adjacent conductive paths, as the distance between the conductors decreases, the resulting capacitance, a function of the dielectric constant (k) of the insulating material divided by the distance between conductive paths, increases. This increased capacitance results in increased capacitive coupling between the conductors, increased power consumption and an increase in the RC time constant. Therefore, continued improvement in semiconductor IC performance and functionality is dependent upon developing materials that form a dielectric film with a lower dielectric constant (k) than that of the most commonly used material, silicon oxide, thus resulting in reduced capacitance. As the dimensions of these devices get smaller and smaller, significant reductions in capacitance, into the so-called ultra low-k (k<2.5) regime, are desirable.

The initial approach for providing reduced-k insulating films was the doping of the silicon oxide material (k≧3.9) with other components that reduce the k value. For example, doping silicon oxide with fluorine typically reduces the value of k, but only to about 3.5-3.9. Processes for forming these doped films often advantageously use the same or similar methods that are used for forming undoped silicon oxide films. Hence the integration of fluorine doped films into the typical process flow is generally easily accomplished. However, as such fluorine doped films offer only a small decrease in k, other solutions having lower dielectric constants are needed. Finally, the stability of such fluorine containing films with regard to moisture is problematic.

A number of families of organic polymers were another preliminary solution for providing low-k dielectric films. Typically, organic polymers can form dielectric films where a k in the range of 2.5 or higher is possible. Generally, such dielectric films are formed by first applying a solution of an appropriate pre-polymer to a substrate. The substrate is then heated until the pre-polymer crosslinks and polymerizes to the degree desired and a solid film formed. As the organic material is applied as a liquid, some degree of surface planarization is provided for and often no additional planarization is needed. However organic polymer films have disadvantages. For example, organic materials generally have limited thermal stability above 450 degrees Centigrade (° C.); they often exhibit less adhesion to common metals, such as tungsten (W) and aluminum (Al); and the mechanical strength of such organic films can be less than that of silicon oxide. Finally, such organic films typically provide for k values only in the “low-k” regime (e.g. k=2.7-3.0).

In an approach for providing a silicon oxide layer having a planar surface, spin-on glass (SOG) compositions have been prepared utilizing polyorganosilsesquioxanes; for example, see U.S. Pat. No. 4,670,299 issued to Fukuyama et al. (Fukuyama '299). The SOG compositions of Fukuyama '299 are silylated polyorganosilsesquioxanes. The compositions are applied in a manner similar to that described previously for the organic polymers and then heated to form a solid polymerized film. The advantage of films of this type, i.e. films of organic polysilica in the form of an polyorganosilsesquioxanes (POSQ), is that, (1) they provide for films with low dielectric constants (k=2.6-3.0), and (2) they maintain the higher mechanical strengths of silicon oxide-type materials.

However, it would be advantageous to have a final dielectric film that combines the advantages of a film formed from organic polysilicas such as polyorganosilsesquioxanes with an even lower dielectric constant (k<2.5). The most likely method for achieving this result is to blend the POSQ with another substance with a lower dielectric constant. A substance with a lower dielectric constant is air (k=1.0). So, to achieve lower dielectric constants, porosity needs to be introduced into the POSQ material.

Several methods have been pursued to induce porosity into low dielectric materials, such as organic, low-k polymers or organic polysilica, low-k polymers. Once such method is the synthesis of a block copolymer composed of a high thermal stability, high T_{g} low-k polymer and a second (organic) polymer that is more easily thermally degradable. This method is purported to have the advantage of forming a closed-cell, porous structure upon thermal curing of the material. See Hedrick, et al. (1993) Polymer 34:4717 and Hendrick, et al. (1995) Polymer 36:4855. However, this method is hampered by difficulties in controlling the synthesis and processing steps, and limits in the thermal stability of the polymer material. Another method utilizes a graft polymerization of a porogenic (i.e. porosity-inducing) organic side-polymer onto a high thermal stability, high T_{g} low-k polymer to form a porous material after thermal treatment; see U.S. Pat. Nos. 6,107,357 and 5,767,014 issued to Hawker, et al., which are incorporated herein by reference. Another method uses polyorganosilanes that are cured in a complex and slow curing process, as described in U.S. Pat. No. 6,162,743, which is incorporated herein by reference. However, these methods introduce processing complexities and are slow.

Therefore, there is a need for an ultra low k dielectric film useful for the fabrication of IC devices, where the film is mechanically strong, useful at high temperatures, and is easily and quickly fabricated.

### SUMMARY OF THE INVENTION

The present invention addresses a solution to this need in the art, by providing novel ultra low dielectric materials comprised of a porous organic polysilica structure with simplified chemistry and processing and a simple method of preparing the materials. The materials have an open or closed-cell structure, with pores in the size regime of <100 Å in diameter, dielectric constants of <2.5, thermal stabilities of over 450° C., good mechanical properties, and superior integration properties.

The materials are prepared from a novel composition comprising: (i) a polymer precursor that upon heating to a cure temperature cross-links to form an organic polysilica layer and (ii) a sufficient amount of porogen that the layer has a porosity of at least about 5%, and preferably up to about 80%. The porogen, which is also referred to herein as a decomposable polymer, decomposes at a decomposition temperature greater than the cure temperature, to form a gas phase that is non-deleterious to the cured polymer precursor and diffuses out of the layer. The decomposition temperature is sufficiently low that the organic polysilica layer is not deleteriously affected at the decomposition temperature. The porogen is non-reactive with the polymer precursor and the organic polysilica layer. Pores formed by the porogen can be substantially spherical and can have a diameter in the range about 10 Å to about 100 Å. The porogen can be an organic dendrimer polymer or a hyperbranched organic polymer. The polymer can be a polyorganosilsesquioxane (POSQ). The composition can contain an adhesion promoter and/or a surfactant. The composition can be applied to a substrate and lithographically patterned. A metallic film can be deposited onto the patterned composition and planarized so that an integrated circuit is formed. The formed porous layer contains substantially no porogen or its decomposition product(s).

The invention also provides for a process for forming the porous layer, preferably for use in an integrated circuit (“IC”). The process comprises the steps of: (a) positioning on a substrate a layer of the novel composition; and (b) heating the composition to a cure temperature and to a decomposition temperature so that the polymer precursor cross-links to form an organic polysilica and the porogen polymer decomposes to form a porous dielectric layer. Typically the composition is provided dissolved in a solution, such as a spinning solution. In the case of an IC, the process can include the additional steps of (c) lithographically patterning the dielectric layer; (d) depositing a metallic film onto the patterned dielectric layer; and (e) planarizing the film to form the integrated circuit. The cure temperature typically is in the range of about 100° C. to about 200° C. The decomposition temperature typically is from about 300° C. to about 450° C. The heating typically takes place in an atmosphere of inert gas.

These and other features, aspects, and advantages of the present invention will become better understood with reference to the following description and appended claims.

### DESCRIPTION OF THE INVENTION

Process for Preparing Ultra Low-k Dielectric Material

The process involves preparing a blend solution of (1) a thermally stable, low dielectric constant, organic-inorganic hybrid host polymer, (2) a thermally degradable organic polymer acting as a porogen (i.e. a porosity-inducing material), and in some embodiments (3) a trace amount of a second organic-inorganic polymer as an adhesion promoter, and/or (4) a trace amount of a surfactant to promote solubility, all in a suitable solvent (e.g. an alcohol). This blend solution can then be spun into films, which can then be thermally cured to eliminate the porogen. The result is a film of porous, ultra low-k material.

1. The Host Polymer/Low-k Material

The host polymer preferably is an organic-inorganic hybrid polymer, i.e. organic polysilica, specifically polyorganosilsesquioxane (POSQ) of the type (RSiO_{1.5})ₙ where R is an organic substituent (e.g. methyl, ethyl, phenyl, etc.) and where the POSQ can be in a mixture with up to 80% (SiO₂)ₙ. This silsesquioxane polymer is synthesized by the acid-catalyzed condensation, via refluxing, of the polymer precursors. In an exemplary embodiment, the synthesis of methylsilsesquioxane (MSQ), the syntheses utilizes a 1.00:1.90 ratio of the MSQ precursor(s) and water in a mixture. The MSQ “precursors” can be a 0-80% portion of tetraethoxysilane (TEOS) and a 20-100% portion of methyltriethoxysilane (MeTEOS). All percentages herein are by weight unless it is indicated otherwise. For example, in one such embodiment of a small scale synthesis of 20% TEOS/80% MeTEOS-based MSQ involves 9.54 g (45.8 mmol) of TEOS, 32.66 g (183 mmol) of MeTEOS, 7.63 g of water and 0.20 g of 1.0 M aqueous HCl (to obtain 0.1% trace of HCl acid to catalyze the reaction). Optionally, 40% TEOS/60%METOS can be used. Refluxing conditions involve heating this mixture to 90-150° C. The reaction time can vary from 6 hours to near the gelation point of the product (>100 hours). After completion of the reflux and the reaction, all of the result MSQ product tends to be a “cloudy” liquid; filtration through 5 μm Teflon filters makes this product clear. These products are refrigerated after synthesis until use. In some embodiments, further post-reflux treatment involves vacuum distillation of the product to reduce the mass of the product 0-60%. The final molecular weight (Mn) of the product can be 1,000 or more, provided it remains soluble in a solvent (e.g., an alcohol).

2. The Porogen

The porogen (i.e. porosity-inducing material) is a thermally degradable organic polymer, which, upon thermal curing, completely degrades to small, gaseous, non-reactive species at a temperature above the crosslinking temperature of the host polymer. These small, gaseous, non-reactive degradation species then diffuse out of the host material, leaving behind hollow pores (i.e. porosity) in the host polymer. The crosslinking temperature of the host polymer (e.g. MSQ, etc.) is usually on the order of 100-200° C., so the degradation temperature of the organic porogen needs to be above this temperature, and is typically from about 250 to about 350° C.

Preferably, but not necessarily, the porogen has the following properties:

1. A decomposition temperature less than a temperature at which the host or base polymer is adversely affected such as glass transition temperature of the host polymer.

2. A decomposition temperature greater than the cross link temperature or cure temperature of the host polymer.

3. Upon decomposition it yields gaseous decomposition products.

4. The decomposition products are not products, such as ammonia, that can be deleterious to the properties of the base polymer.

5. The gaseous decomposition products diffuse out of base polymer.

6. A volume sufficiently large to leave pores of at least 10 Angstrom in diameter (as measured by transmission electron microscopy). The diameter measured is actually an “equivalent” diameter since the pores are not perfectly spherical. Pores smaller than 10 Angstroms generally will not yield a sufficient total porosity to reduce the dielectric constant to the ultra low range.

7. A volume not so large as to leave pores of greater than 100 Angstroms in diameter. A reason for this is that IC trenches typically are about 1000 angstrom thick. If the pores are too large, the pores can provide a channel for electrical connection. It is typical in the IC industry to limit pore size to no more than 10% of trench thickness.

8. Non-reactive with the polymer precursor and base polymer, either directly or through the use of a coupling agent. The term “non-reactive” as used herein, including in the claims, means the porogen does not chemically react, either directly or through a coupling agent, with the polymer precursor or base polymer.

9. Non-deleterious to the properties, including the mechanical properties, of the base polymer.

10. Does not decompose or otherwise degrade at the cure temperature.

11. Dissolves in a solvent, such as the solvent used in a spinning solution used for fabrication of an integrated circuit.

It is preferable that the pores generated in the host material be of regular, and reproducible, geometric shape (e.g. spherical pores of all the same diameter and volume). Generally, organic dendrimer polymers or hyperbranched organic polymers are the best candidates as porogens with these specific properties, substantially improving reproducibility over linear polymers. A dendrimer is a polymer in which the atoms are arranged in many branches and subbranches along a central backbone of carbon atoms. Linear polymers may have greater molecular weight and size distributions, and are much less adept at producing regular (i.e. spherical) and reproducible pores and pore sizes in a material. One class of suitable hyperbranched organic polymeric porogens, with both regular, reproducible sizes, and thermal degradation temperatures above 300° C., are hyperbranched polyesteramides. Another class of organic polymer dendrimers is poly(propylene imines). Both of these classes of porogens can be obtained commercially (e.g. the hyperbranched polyesteramide Hybrane™ polymers, and the ASTRAMOL™ porogen polymers, from DSM Research, Geleen, The Netherlands).

The general molecular structure of the hyperbranched polyesteramide Hybrane™ polymer is shown below. The general structure of the Hybrane™ polymer shown below is based on a specific polymer precursor (e.g. hexahydrophtlalic anhydride, see below). Other Hybrane™ polymers, based on other precursors, are also available.

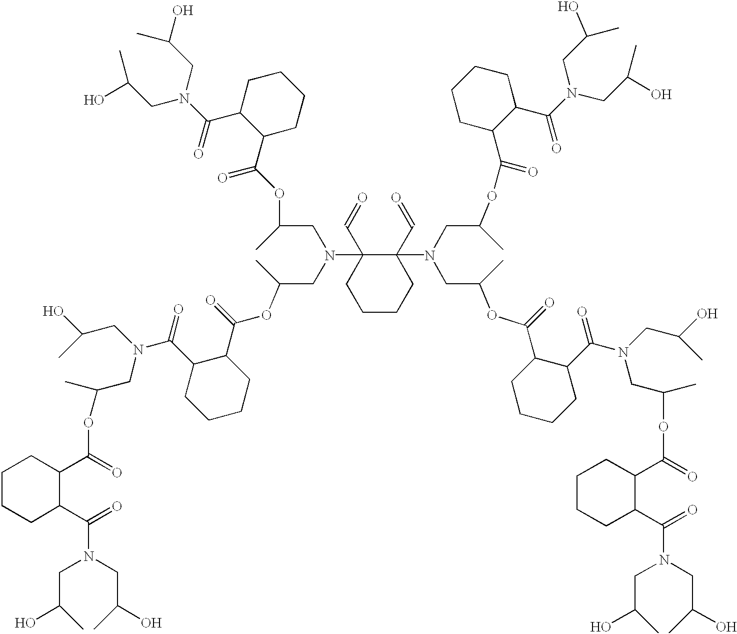

For example, the precursors, and the structures of each precursor, for several sample hyperbranched Hybrane™ polymer analogues are as follows:

1) HL3800 & HL4095—dendrimer core: hexahydrophtlalic anhydride (HHPA), diisopropanolamine (DPA); dendrimer shell groups from: 10 lauric acids (LA)

2) PL2895—dendrimer core: phtlalic anhydride (PA), diisopropanolamine (DPA); dendrimer shell groups from: 8 lauric acids (LA)

3) SL2695—dendrimer core: succinic anhydride (SA), diisopropanolamine (DPA); dendrimer shell groups from: 7.6 lauric acids (LA) & 0.4 hydroxyl

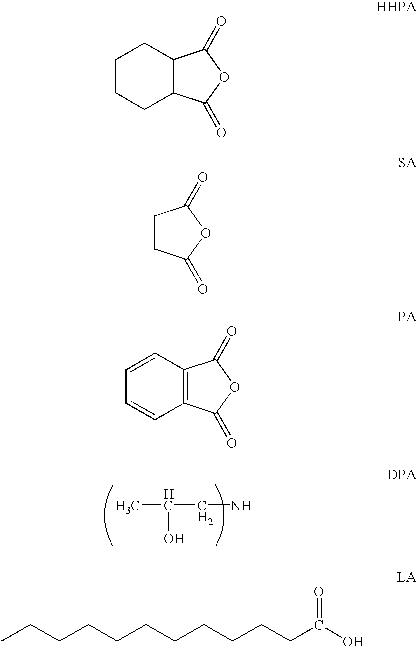

In the case of these hyperbranched polymers, the endgroups tends to be long chain alkyls. The same is true of the poly(propylene imine) ASTRAMOL™ dendrimer polymers. The structure of an poly(propylene imines) ASTRAMOL™ dendrimer polymer is shown below.

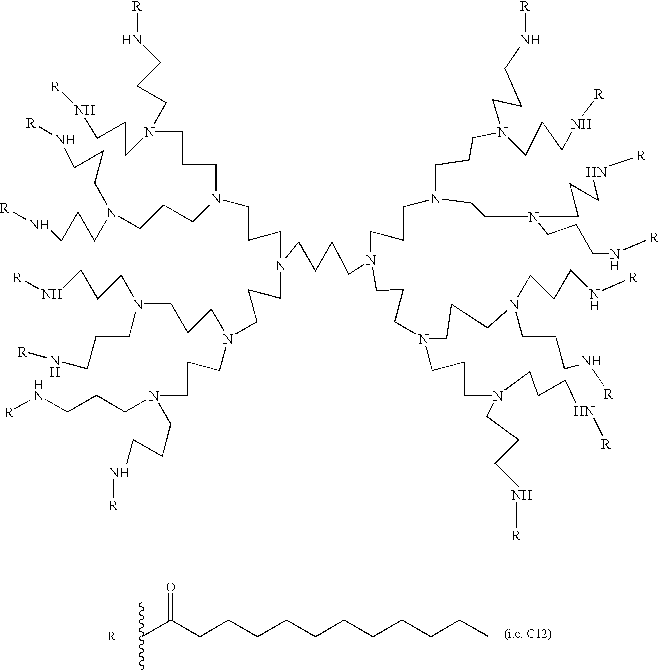

Many of these hyperbranched polyesteramide Hybrane™ polymers, and many of the poly(propylene imines) ASTRAMOL™ dendrimer polymers, are soluble in alcohols, and so are suitable porogens for the host polymer.

The amount of porogen versus the amount of host polymer determines the porosity of the resulting dielectric layer. Typically there is sufficient porogen that the pores are at least 10% of the volume of the layer. As the percentage of pores increases, the mechanical properties of the layer worsen, thereby resulting in loss of structural integrity. Accordingly, the amount of porogen is limited so that the pores are no more than 80%, and preferably no more than 50% of the volume of the layer.

3. The Adhesion-Promoter Polymer

In some embodiments of this invention, an adhesion promoter is added to the solution of host polymer and porogen to improve adhesion to the substrate to which the film is applied. When used in IC applications, the underlying substrate can be made of materials such as silica or titanium nitride. Organic-inorganic hybrid polymers, such as polycarbosilane, are known to have very good adhesion properties upon thermal curing. One such example is the hydridopolycarbosilane (HPCS) analogue of polycarbosilane.; the structure of hydridopolycarbosilane (HPCS) is shown below:

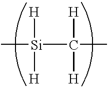

This polymer can easily be obtained commercially (e.g. HPCS from Starfire Systems of Watervliet, N.Y.), as can other analogues of polycarbosilane. When an adhesion promoter is desired, a small amount (<5%) of such a second organic-inorganic polymer is added to the solution of host polymer and porogen, to facilitate the adhesion of the material, when this solution is spun into a film and thermally cured.

4. The Surfactant

In some embodiments of this invention, a surfactant can be added to the solution of the host polymer and porogen to improve film quality. A surfactant can promote solubility when added to this solution. Surfactants are generally organic, and often halogenated, and can be easily obtained commercially (e.g. FC430 from 3M Corp.). When needed, a trace amount of such surfactant is added. This facilitates the formation of high quality films from spinning.

5. Crosslinking and Thermolysis

A solution of the host organic polysilica polymer, the organic porogen, and in some embodiments, the adhesion promoter and/or the surfactant, typically at a solid content of about 40% to about 50% based on the total weight of the solution, is generally spin-coated in the form of a film onto a substrate or applied to the substrate by any means known in the art. The thickness of such film can be anywhere from less than 0.5 μm (5,000 Å) to 2 μm (20,000 Å). Typical of the solvents that can be used are alcohols, such as isopropyl alcohol, butanol, and mixtures thereof; and ketones, such as acetone.

The crosslinking of the low-k host polymer is carried out by thermal curing. The primary steps of the thermal curing are carried out in an inert atmosphere of nitrogen or other inert gases. The polymeric matrix is ramped from room temperature through the crosslinking temperature (100-200° C.) of the organic polysilica matrix polymer. In some cases, a “hold” can be implemented at this crosslinking temperature; in other cases, the temperature ramp continues straight through this crosslinking temperature. At this point in the curing process, the crosslinking of the polymer matrix traps the organic porogen in discrete phases within the continuous phase of the host polymer matrix. The size of these porogen domains is less that 10 nm (100 Å) in diameter, typically less than 5 nm (50 Å) in diameter. The size of these domains is controlled by the porogen size and the phase separation between the host polymer matrix and the organic porogen, a process that is governed by the characteristics and chemical compatibility of these components and the processing conditions of the film-spinning and thermal curing.

Once beyond the crosslinking temperature of the organic polysilica matrix, the temperature is continually ramped to the final “hold” temperature (≧400° C.), which is below the glass transition temperature (T_{g}) of the organic polysilica host polymer. During this portion of the temperature ramp, the organic porogen (e.g. the hyperbranched polyesteramide Hybrane™ polymer, etc.) is heated to above the decomposition temperature (>300° C.) of the porogen. The porogen is thus thermally decomposed to small volatile species, which are eliminated from the polymer matrix, leaving behind voids (i.e. pores) where the organic porogen had phase separated into distinct domains in the host polymer. These pores conform to the size domains of the porogen. The length of the “hold” time at this temperature (≧400° C.) varies from 5 minutes to several hours.

In some embodiments, a subsequent curing step, under reduced atmosphere, and the same or a higher temperature (400-450° C.) is also carried out.

An advantage of the present invention is that the cured low-K film can be formed very quickly. Unlike prior art systems which require a slow heating step because of the reaction between the polymer precursor/host material and the porogen, the matrix material and the porogen of the present invention need not react with each other. Thus a slow heating step is not needed. In such a slow heating step, the materials can require as much as 1 hour to be heated to the cure temperature. In the present invention, the materials can be heated up to the decomposition temperature as quickly as the heating equipment can perform the task, such as at a rate of 30° C./minute or higher, so that the composition can be heated to the porogen decomposition temperature in less than 10 minutes. The amount of time includes the time to heat the composition to the desired temperature and any “hold” time for curing and/or decomposition and release of the porogen. For example, a “hot plate” cure can be used. In a “hot plate” cure, the heating media is maintained at an elevated temperature at all times, as opposed to a furnace cure where the furnace starts at room temperature and then ramps up. Since the popular single wafer chip manufacturing method uses a hot plate cure, the present invention can be used in this single wafer manufacturing process. Because of the fast cure, low K materials according to the present invention can be made at high throughput, which makes the economics of using the present invention very attractive.

Not to be bound by theory, it is believed that in prior art systems, it is necessary for the porogen to react with the polymer precursor or else the porogens agglomerate, thereby resulting in formation of a small number of very large pores. The use of the preferred porogens described herein avoids this problem.

In some embodiments, other treatment steps can be carried out on the resulting film(s) to further improve materials properties. See for example “Plasma Curing of MSQ-Based Porous Low-K Film Materials”, filed Jul. 16, 2001, U.S. patent application Ser. No. 09/906,276, which is incorporated herein by reference.

When forming an IC, the metallic conductor, such as copper, can be deposited on a silica substrate before forming the dielectric layer. Alternatively, the dielectric layer can be formed first, trenches can be carved in the dielectric layer, and the metallic conductor is deposited in the trenches (damascene method). The material of the present invention can be used in both methods.

In some embodiments of the present invention, the polymer film is formed and cured to a (POSQ) film having a thickness of between approximately 0.3 to 0.7 microns (μm) and is employed in a damascene process. In some embodiments of the present invention, the POSQ film is formed having a thickness of between approximately 0.7 to 1.25 μm and employed in a double damascene process. While in other embodiments the POSQ film is formed having a thickness of between approximately 1.3 to 1.5 μm on a patterned wafer and employed as an interlayer dielectric or passivation layer. In some embodiments, one or more POSQ film layers are formed to provide a microelectronic device having a multi-layer interconnect structure.

The Novel Ultra Low-k Dielectric Material

The dielectric material prepared using the methodology described in the preceding section is thus a porous polymer with a number of advantageous properties. The material has a dielectric constant of less than 3, and preferably significantly less, such as less than 2.5 and typically 2.2-2.5 or even less than 2.2, at 25° C. In addition, the material has pores sizes generally less than 10 nm (100 Å), preferably less than 5 nm (50 Å), in diameter, and a porosity level of 5% or greater, resulting in enhanced mechanical toughness.

Although the present invention has been described in considerable detail with reference to certain preferred versions thereof, other versions are possible.

Therefore, the spirit and scope of the appended claims should not be limited to the description of the preferred versions contained herein.

All features disclosed in the specification, including the claims, abstracts, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent or similar purpose, unless expressly stated otherwise. Thus, unless expressly stated otherwise, each feature disclosed is one example only of a generic series of equivalent or similar features.

Any element in a claim that does not explicitly state “means” for performing a specified function or “step” for performing a specified function, should not be interpreted as a “means” for “step” clause as specified in 35 U.S.C. § 112.

What is claimed is:

1. A composition, comprising:
(a) a polymer precursor that upon heating to a cure temperature cross-links to form an organic polysilica layer; and
(b) a sufficient amount of porogen that the layer has a porosity of from about 5% to about 80%, wherein the porogen is non-reactive with the polymer precursor, wherein the porogen at a decomposition temperature greater than the cure temperature decomposes to form a gas phase that is non-deleterious to the organic polysilica layer and diffuses out of the layer, and wherein the decomposition temperature is sufficiently low so that the organic polysilica layer is not deleteriously affected at the decomposition temperature.

2. The composition of claim 1 wherein the porogen is an organic dendrimer polymer.

3. The composition of claim 1 wherein the porogen is hyperbranched organic polymer.

4. The composition of claim 1 wherein the polymer precursor is a polyorganosilsesquioxane.

5. The composition of claim 1 further comprising an adhesion promoter.

6. The composition of claim 1 further comprising a surfactant.

7. The composition of claim 1 wherein the layer formed contains substantially no porogen or its decomposition products.

8. The composition of claim 1 or 3 wherein the porogen is a polyesteramide.

9. The composition of claim 1 or 2 wherein the porogen is a poly (propylene imine).

10. A dielectric material formed by heating the composition of claim 1 to a temperature greater than the decomposition temperature of the porogen.

11. The dielectric material of claim 10 having substantially spherical pores with a diameter in the range of about 10 Å to about 100 Å.

12. A process for forming an integrated circuit, comprising the steps of:
(a) positioning on a substrate a layer of dielectric composition comprising a decomposable polymer and a polymer precursor that cures at a cure temperature to form an organic polysilica layer, wherein the decomposable polymer is non-reactive with the polymer precursor; and
(b) heating the dielectric composition to a cure temperature and to a decomposition temperature so that the polymer precursor cross-links to form an organic polysilica and the decomposable polymer decomposes to form pores in the organic polysilica layer.

13. The process of claim 12 comprising the additional steps of:
(c) lithographically patterning the dielectric layer; and
(d) depositing a metallic film onto the patterned dielectric layer.

14. The process of claim 12 wherein the decomposition temperature is greater than the cure temperature and wherein the decomposition temperature is sufficiently low that the organic polysilica layer is not deleteriously affected at the decomposition temperature.

15. The process of claim 12 wherein the cure temperature is from about 100° C. to about 200° C. and the decomposition temperature is from about 300° C. to about 450° C.

16. The process of claim 12 wherein the heating takes place in an atmosphere of inert gas.

17. A process for forming an integrated circuit, comprising the steps of:
(a) depositing a metallic film on a substrate;
(b) lithographically patterning the metallic film;
(c) depositing on the patterned metallic film, a layer of a dielectric composition comprising a polymer precursor and a decomposable polymer, wherein the decomposable poly, wherein the decomposable polymer is non-reactive with the polymer precursor; and
(d) heating the composition to a cure temperature and to a decomposition temperature so that the polymer precursor cross-links to form an organic polysilica and so that the decomposable polymer decomposes to form a porous dielectric layer.

18. The dielectric material of claim 11 having a dielectric constant of less than 2.5.

19. The process of claim 12 wherein the porous polysilica layer has a dielectric constant of less than 2.5.

20. The process of claim 17 wherein the dielectric layer has a dielectric constant of less than 2.5.

21. The process of claim 12 or 17 wherein the step of heating comprises heating the composition at a rate of greater than 30° C./minute.

22. The process of claim 12 or 17 wherein the step of heating comprises heating the composition to the decomposition temperature in less than 10 minutes.

23. The composition of claim 1 in a solvent which dissolves both the polymer precursor and the porogen.

24. The process of claim 12 or 17 wherein the dielectric composition is dissolved in a solvent.
